(19) United States
(12) Patent Application Publication
(10) Pub. No.: US 2011/0215299 A1
(43) Pub. Date: Sep. 8, 2011

(54) SEMICONDUCTOR DEVICE INCLUDING A SUPERLATTICE AND DOPANT DIFFUSION RETARDING IMPLANTS AND RELATED METHODS

(75) Inventor: KALIPATNAM RAO, Grafton, MA (US)

(73) Assignee: MEARS Technologies, Inc., Newton, MA (US)

(21) Appl. No.: 13/042,826

(22) Filed: Mar. 8, 2011

Related U.S. Application Data
(60) Provisional application No. 61/311,454, filed on Mar. 8, 2010.

(51) Int. Cl. H01L 29/15; H01L 21/336

(52) U.S. Cl. 257/28; 438/285; 257/E29.073; 257/E21.409

(57) ABSTRACT

A semiconductor device may include a substrate and at least one MOSFET adjacent the substrate. The MOSFET may include a superlattice channel including a plurality of stacked groups of layers, a source and a drain adjacent the superlattice channel, and a gate adjacent the superlattice channel. Each group of layers of the superlattice channel may include a plurality of stacked base semiconductor monolayers defining a base semiconductor portion and at least one non-semiconductor monolayer constrained within a crystal lattice of adjacent base semiconductor portions. A first dopant may be in at least one region adjacent at least one of the source and drain, and a second dopant may also be in the at least one region. The second dopant may be different than the first dopant and reduce diffusion thereof.

### RELATED APPLICATIONS

This application is based upon prior filed provisional application Ser. No. 61/311,454 filed Mar. 8, 2010, the disclosure of which is incorporated herein by reference in its entirety.

### FIELD OF THE INVENTION

The present invention relates to the field of semiconductors, and, more particularly, to semiconductor devices comprising superlattices and associated methods.

### BACKGROUND OF THE INVENTION

As metal-oxide semiconductor (MOS) transistors are scaled down with successive generations of technology, short-channel effects (SCE) become a dominant factor in restricting device functionality. Boron implants are used by the semiconductor industry to optimize MOS transistor performance. For instance, p-well and Vt-adjust implants are performed using boron implants. The source-drain extensions (SDE) and source-drain regions for PFET devices include boron implants. NFET devices use halo implants with boron precisely placed at channel edges to mitigate SCE.

When high-mobility semiconductor materials involving superlattice structures are used in the transistor channel, there is enhanced performance for long-channel transistors. However, for short-channel devices (e.g., <0.3 μm) there may be a propensity to not completely realize the performance enhancement seen for long-channel devices. This may potentially be traced to anomalous enhanced lateral boron diffusion. For PFET's there may be enhanced lateral diffusion from the source-drain extension (SDE)/deep source-drain regions into the channel. For NFET's, the lateral spread of boron into the channel along the superlattice increases the threshold voltage of the device. As such, these phenomena may diminish the advantages achieved by the use of advanced, high-mobility semiconductor materials that would otherwise enhance transistor performance.

In an article by Li et al. entitled “Boron Retarded Diffusion in the Presence of Indium or Germanium,” Electron Device Letters, IEEE, November 2002, volume 23, issue 11, pages 646-648, the authors reported the use of any of several elements (N/Ge/F/Al/Ga/In) co-implanted with boron to retard boron diffusion. In other cases, the boron halo implant is fully replaced with indium implants. In both cases, the authors built MOS devices using only conventional silicon substrates.

Generally, such previous efforts to retard boron diffusion have been focused to obtaining shallower junctions with lower sheet resistance. The mechanism of retardation of boron diffusion in the presence of In or Ge is ascribed to be due to formation of clusters of B—In or B—Ge due to the strain associated with the larger lattice parameter.

### SUMMARY OF THE INVENTION

A semiconductor device may include a substrate and at least one MOSFET adjacent the substrate. The MOSFET may include a superlattice channel including a plurality of stacked groups of layers, a source and a drain adjacent the superlattice channel, and a gate adjacent the superlattice channel. Each group of layers of the superlattice channel may include a plurality of stacked base semiconductor monolayers defining a base semiconductor portion and at least one non-semiconductor monolayer constrained within a crystal lattice of adjacent base semiconductor portions. A first dopant may be in at least one region adjacent at least one of the source and drain, and a second dopant may also be in the at least one region. The second dopant may be different than the first dopant and advantageously reduce diffusion thereof, such as into the superlattice channel, for example.

More particularly, the at least one region may comprise a halo region adjacent the source and drain. Furthermore, the at least one region may comprise a source extension region adjacent the source and a drain extension region adjacent the drain. The at least one region may also comprise a deep source region adjacent the source and a deep drain region adjacent the drain.

By way of example, the first dopant may comprise boron, and the second dopant may comprise at least one of nitrogen, germanium, fluorine, aluminum, gallium, indium, and carbon. The semiconductor device may further include a contact layer on at least one of the source and drain regions. Also by way of example, each base semiconductor portion may comprise at least one of silicon and germanium. The at least one non-semiconductor monolayer may comprise a non-semiconductor selected from the group consisting of oxygen, nitrogen, fluorine, and carbon-oxygen, for example.

In particular, the gate may include an oxide layer overlying the superlattice channel and a gate electrode overlying the oxide layer. Furthermore, the superlattice channel may further include a base semiconductor cap layer on an uppermost group of layers. Additionally, at least some semiconductor atoms from opposing base semiconductor portions may be chemically bound together through the non-semiconductor layer therebetween.

A related method for making a semiconductor device may include forming at least one MOSFET adjacent a substrate, such as the MOSFET described briefly above.

### BRIEF DESCRIPTION OF THE DRAWINGS

FIG. 1 is a greatly enlarged schematic cross-sectional view of a superlattice for use in a semiconductor device in accordance with the present invention.

FIG. 2 is a perspective schematic atomic diagram of a portion of the superlattice shown in FIG. 1.

FIG. 3 is a greatly enlarged schematic cross-sectional view of another embodiment of a superlattice in accordance with the invention.

FIG. 4A is a graph of the calculated band structure from the gamma point (G) for both bulk silicon as in the prior art, and for the 4/1 Si/O superlattice as shown in FIGS. 1-2.

FIG. 4B is a graph of the calculated band structure from the Z point for both bulk silicon as in the prior art, and for the 4/1 Si/O superlattice as shown in FIGS. 1-2.

FIG. 4C is a graph of the calculated band structure from both the gamma and Z points for both bulk silicon as in the prior art, and for the 5/1/3/1 Si/O superlattice as shown in FIG. 3.

FIG. 5 is a schematic block diagram of a MOSFET including source/drain extension implants in accordance with the present invention.

FIG. 6 is a schematic block diagram of a MOSFET including halo implants in accordance with the present invention.

FIG. 7 is a schematic block diagram of a MOSFET including deep source and drain implants in accordance with the present invention.

### DETAILED DESCRIPTION OF THE PREFERRED EMBODIMENTS

The present invention will now be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout, and prime and multiple-prime notation are used to indicate similar elements in different embodiments.

The present invention relates to controlling the properties of semiconductor materials at the atomic or molecular level. Further, the invention relates to the identification, creation, and use of improved materials for use in semiconductor devices, as well as to the implementation of such materials in devices while controlling undesired dopant diffusion that may reduce the enhanced operating characteristics of such materials.

Applicants theorize, without wishing to be bound thereto, that certain superlattices as described herein reduce the effective mass of charge carriers and that this thereby leads to higher charge carrier mobility. Effective mass is described with various definitions in the literature. As a measure of the improvement in effective mass Applicants use a “conductivity reciprocal effective mass tensor”, Mₑ⁻¹ and Mₕ⁻¹ for electrons and holes respectively, defined as:

$${M}_{e , i , j}^{- 1} ( {E}_{F} , T ) = \frac{{\sum }_{E > {E}_{F}} {\int }_{B . Z .} {( {∇}_{k} E ( k , n ) )}_{i} {( {∇}_{k} E ( k , n ) )}_{j} \frac{\partial f ( E ( k , n ) , {E}_{F} , T )}{\partial E} {d}^{3} k}{{\sum }_{E > {E}_{F}} {\int }_{B . Z .} f ( E ( k , n ) , {E}_{F} , T ) {d}^{3} k}$$

for electrons and:

$${M}_{h , i , j}^{- 1} ( {E}_{F} , T ) = \frac{- {\sum }_{E < {E}_{F}} {\int }_{B . Z .} {( {∇}_{k} E ( k , n ) )}_{i} {( {∇}_{k} E ( k , n ) )}_{j} \frac{\partial f ( E ( k , n ) , {E}_{F} , T )}{\partial E} {d}^{3} k}{{\sum }_{E < {E}_{F}} {\int }_{B . Z .} ( 1 - f ( E ( k , n ) , {E}_{F} , T ) ) {d}^{3} k}$$

for holes, where f is the Fermi-Dirac distribution, E_{F} is the Fermi energy, T is the temperature, E(k,n) is the energy of an electron in the state corresponding to wave vector k and the n^{th} energy band, the indices i and j refer to Cartesian coordinates x, y and z, the integrals are taken over the Brillouin zone (B.Z.), and the summations are taken over bands with energies above and below the Fermi energy for electrons and holes respectively.

Applicants' definition of the conductivity reciprocal effective mass tensor is such that a tensorial component of the conductivity of the material is greater for greater values of the corresponding component of the conductivity reciprocal effective mass tensor. Again Applicants theorize without wishing to be bound thereto that the superlattices described herein set the values of the conductivity reciprocal effective mass tensor so as to enhance the conductive properties of the material, such as typically for a preferred direction of charge carrier transport. The inverse of the appropriate tensor element is referred to as the conductivity effective mass. In other words, to characterize semiconductor material structures, the conductivity effective mass for electrons/holes as described above and calculated in the direction of intended carrier transport is used to distinguish improved materials.

Applicants have identified improved materials or structures for use in semiconductor devices. More specifically, the Applicants have identified materials or structures having energy band structures for which the appropriate conductivity effective masses for electrons and/or holes are substantially less than the corresponding values for silicon. In addition to the enhanced mobility characteristics of these structures, they may also be formed or used in such a manner that they provide piezoelectric, pyroelectric, and/or ferroelectric properties that are advantageous for use in a variety of different types of devices, as will be discussed further below.

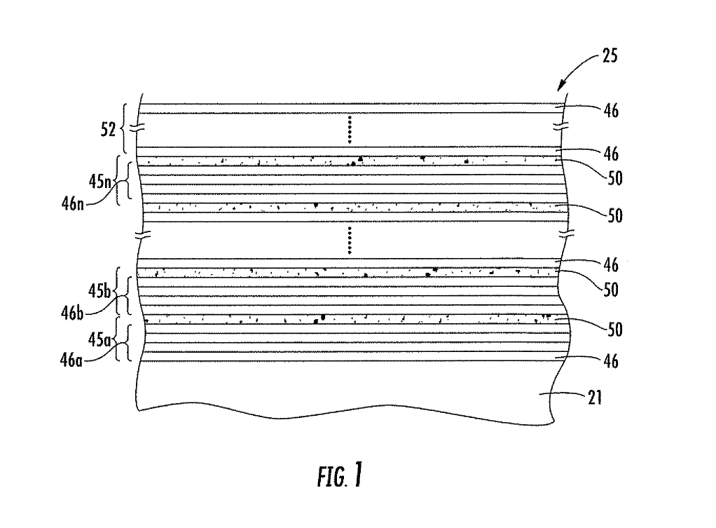

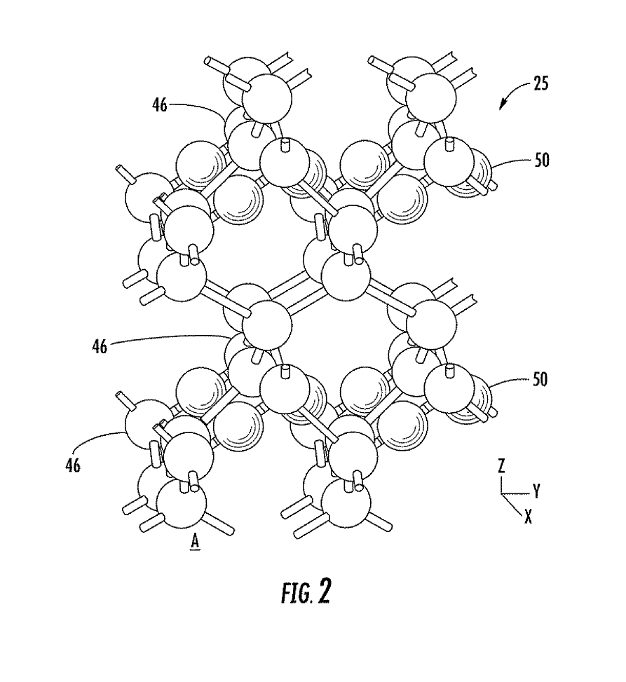

Referring now to FIGS. 1 and 2, the materials or structures are in the form of a superlattice 25 whose structure is controlled at the atomic or molecular level and may be formed using known techniques of atomic or molecular layer deposition. The superlattice 25 includes a plurality of layer groups 45a-45n arranged in stacked relation, as perhaps best understood with specific reference to the schematic cross-sectional view of FIG. 1.

Each group of layers 45a-45n of the superlattice 25 illustratively includes a plurality of stacked base semiconductor monolayers 46 defining a respective base semiconductor portion 46a-46n and an energy band-modifying layer 50 thereon. The energy band-modifying layers 50 are indicated by stippling in FIG. 1 for clarity of illustration.

The energy band-modifying layer 50 illustratively includes one non-semiconductor monolayer constrained within a crystal lattice of adjacent base semiconductor portions. By “constrained within a crystal lattice of adjacent base semiconductor portions” it is meant that at least some semiconductor atoms from opposing base semiconductor portions 46a-46n are chemically bound together through the non-semiconductor monolayer 50 therebetween, as seen in FIG. 2. Generally speaking, this configuration is made possible by controlling the amount of non-semiconductor material that is deposited on semiconductor portions 46a-46n through atomic layer deposition techniques so that not all (i.e., less than full or 100% coverage) of the available semiconductor bonding sites are populated with bonds to non-semiconductor atoms, as will be discussed further below. Thus, as further monolayers 46 of semiconductor material are deposited on or over a non-semiconductor monolayer 50, the newly deposited semiconductor atoms will populate the remaining vacant bonding sites of the semiconductor atoms below the non-semiconductor monolayer.

In other embodiments, more than one such non-semiconductor monolayer may be possible. It should be noted that reference herein to a non-semiconductor or semiconductor monolayer means that the material used for the monolayer would be a non-semiconductor or semiconductor if formed in bulk. That is, a single monolayer of a material, such as silicon, may not necessarily exhibit the same properties that it would if formed in bulk or in a relatively thick layer, as will be appreciated by those skilled in the art.

Applicants theorize without wishing to be bound thereto that energy band-modifying layers 50 and adjacent base semiconductor portions 46a-46n cause the superlattice 25 to have a lower appropriate conductivity effective mass for the charge carriers in the parallel layer direction than would otherwise be present. Considered another way, this parallel direction is orthogonal to the stacking direction. The band-modifying layers 50 may also cause the superlattice 25 to have a common energy band structure. The band modifying layers 50 may also cause the superlattice 25 to have a common energy band structure, while also advantageously functioning as an insulator between layers or regions vertically above and below the superlattice.

Moreover, this superlattice structure may also advantageously act as a barrier to dopant and/or material bleed between layers vertically above and below the superlattice 25. These properties may thus advantageously allow the superlattice 25 to provide an interface for high-K dielectrics which not only reduces bleeding of the high-K material into the channel region, but which may also advantageously reduce unwanted scattering effects and improve device mobility, as will be appreciated by those skilled in the art.

It is also theorized that semiconductor devices including the superlattice 25 may enjoy a higher charge carrier mobility based upon the lower conductivity effective mass than would otherwise be present. In some embodiments, and as a result of the band engineering achieved by the present invention, the superlattice 25 may further have a substantially direct energy bandgap that may be particularly advantageous for opto-electronic devices, for example.

The superlattice 25 also illustratively includes a cap layer 52 on an upper layer group 45n. The cap layer 52 may comprise a plurality of base semiconductor monolayers 46. The cap layer 52 may have between 2 to 100 monolayers of the base semiconductor, and, more preferably between 10 to 50 monolayers.

Each base semiconductor portion 46a-46n may comprise a base semiconductor selected from the group consisting of Group IV semiconductors, Group III-V semiconductors, and Group II-VI semiconductors. Of course, the term Group IV semiconductors also includes Group IV-IV semiconductors, as will be appreciated by those skilled in the art. More particularly, the base semiconductor may comprise at least one of silicon and germanium, for example.

Each energy band-modifying layer 50 may comprise a non-semiconductor selected from the group consisting of oxygen, nitrogen, fluorine, and carbon-oxygen, for example. The non-semiconductor is also desirably thermally stable through deposition of a next layer to thereby facilitate manufacturing. In other embodiments, the non-semiconductor may be another inorganic or organic element or compound that is compatible with the given semiconductor processing as will be appreciated by those skilled in the art. More particularly, the base semiconductor may comprise at least one of silicon and germanium, for example

It should be noted that the term monolayer is meant to include a single atomic layer and also a single molecular layer. It is also noted that the energy band-modifying layer 50 provided by a single monolayer is also meant to include a monolayer wherein not all of the possible sites are occupied (i.e., there is less than full or 100% coverage). For example, with particular reference to the atomic diagram of FIG. 2, a 4/1 repeating structure is illustrated for silicon as the base semiconductor material, and oxygen as the energy band-modifying material. Only half of the possible sites for oxygen are occupied in the illustrated example.

In other embodiments and/or with different materials this one half occupation would not necessarily be the case as will be appreciated by those skilled in the art. Indeed it can be seen even in this schematic diagram, that individual atoms of oxygen in a given monolayer are not precisely aligned along a flat plane as will also be appreciated by those of skill in the art of atomic deposition. By way of example, a preferred occupation range is from about one-eighth to one-half of the possible oxygen sites being full, although other numbers may be used in certain embodiments.

Silicon and oxygen are currently widely used in conventional semiconductor processing, and, hence, manufacturers will be readily able to use these materials as described herein. Atomic or monolayer deposition is also now widely used. Accordingly, semiconductor devices incorporating the superlattice 25 in accordance with the invention may be readily adopted and implemented, as will be appreciated by those skilled in the art.

It is theorized without Applicants wishing to be bound thereto that for a superlattice, such as the Si/O superlattice, for example, that the number of silicon monolayers should desirably be seven or less so that the energy band of the superlattice is common or relatively uniform throughout to achieve the desired advantages. The 4/1 repeating structure shown in FIGS. 1 and 2, for Si/O has been modeled to indicate an enhanced mobility for electrons and holes in the X direction, For example, the calculated conductivity effective mass for electrons (isotropic for bulk silicon) is 0.26 and for the 4/1 SiO superlattice in the X direction it is 0.12 resulting in a ratio of 0.46. Similarly, the calculation for holes yields values of 0.36 for bulk silicon and 0.16 for the 4/1 Si/O superlattice resulting in a ratio of 0.44.

While such a directionally preferential feature may be desired in certain semiconductor devices, other devices may benefit from a more uniform increase in mobility in any direction parallel to the groups of layers. It may also be beneficial to have an increased mobility for both electrons or holes, or just one of these types of charge carriers as will be appreciated by those skilled in the art.

The lower conductivity effective mass for the 4/1 Si/O embodiment of the superlattice 25 may be less than two-thirds the conductivity effective mass than would otherwise occur, and this applies for both electrons and holes. Of course, the superlattice 25 may further comprise at least one type of conductivity dopant therein, as will also be appreciated by those skilled in the art.

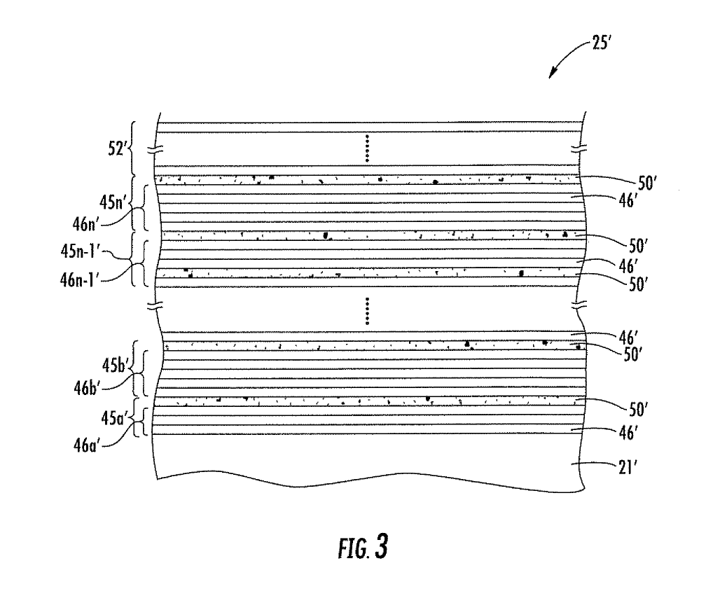

Indeed, referring now additionally to FIG. 3, another embodiment of a superlattice 25′ in accordance with the invention having different properties is now described. In this embodiment, a repeating pattern of 3/1/5/1 is illustrated. More particularly, the lowest base semiconductor portion 46a′ has three monolayers, and the second lowest base semiconductor portion 46b′ has five monolayers. This pattern repeats throughout the superlattice 25′. The energy band-modifying layers 50′ may each include a single monolayer. For such a superlattice 25′ including Si/O, the enhancement of charge carrier mobility is independent of orientation in the plane of the layers. Those other elements of FIG. 3 not specifically mentioned are similar to those discussed above with reference to FIG. 1 and need no further discussion herein.

In some device embodiments, all of the base semiconductor portions of a superlattice may be a same number of monolayers thick. In other embodiments, at least some of the base semiconductor portions may be a different number of monolayers thick. In still other embodiments, all of the base semiconductor portions may be a different number of monolayers thick.

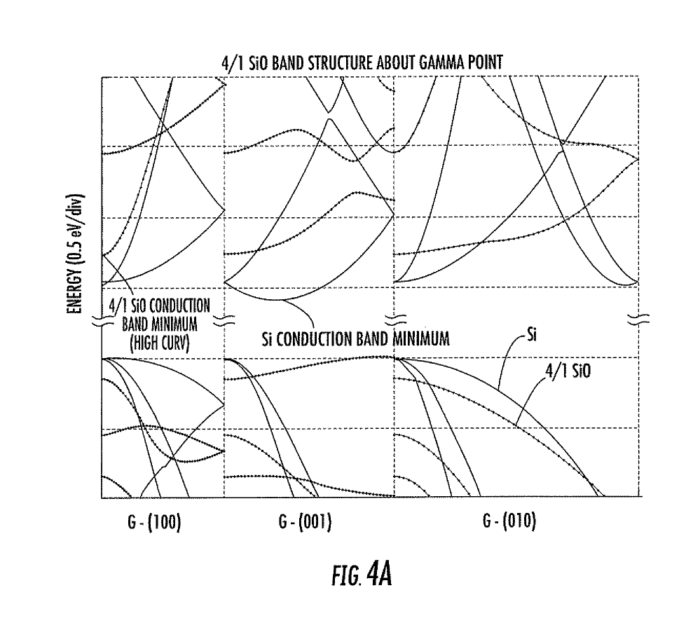

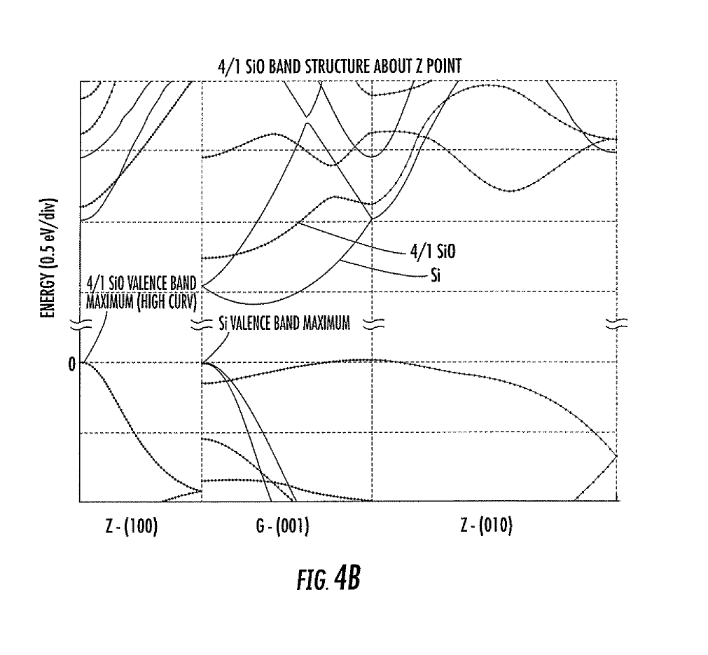

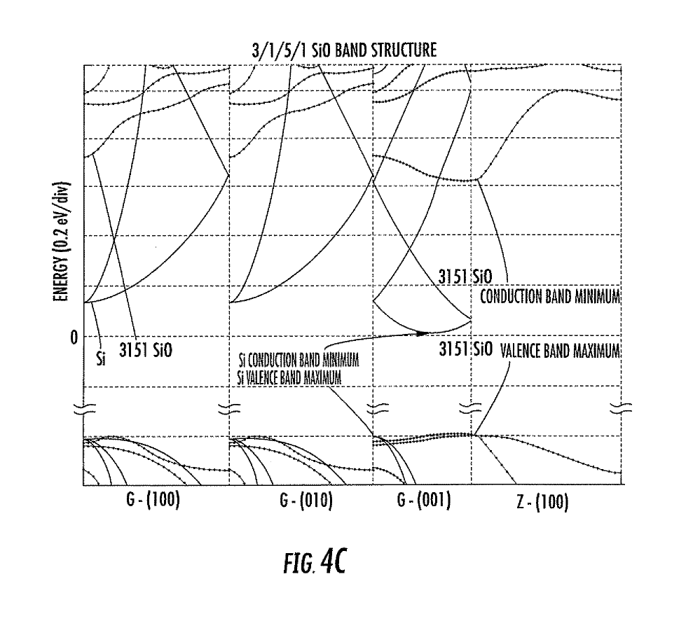

In FIGS. 4A-4C, band structures calculated using Density Functional Theory (DFT) are presented. It is well known in the art that DFT underestimates the absolute value of the bandgap. Hence all bands above the gap may be shifted by an appropriate “scissors correction.” However the shape of the band is known to be much more reliable. The vertical energy axes should be interpreted in this light.

FIG. 4A shows the calculated band structure from the gamma point (G) for both bulk silicon (represented by continuous lines) and for the 4/1 Si/O superlattice 25 shown in FIG. 1 (represented by dotted lines). The directions refer to the unit cell of the 4/1 Si/O structure and not to the conventional unit cell of Si, although the (001) direction in the figure does correspond to the (001) direction of the conventional unit cell of Si, and, hence, shows the expected location of the Si conduction band minimum. The (100) and (010) directions in the figure correspond to the (110) and (−110) directions of the conventional Si unit cell. Those skilled in the art will appreciate that the bands of Si on the figure are folded to represent them on the appropriate reciprocal lattice directions for the 4/1 Si/O structure.

It can be seen that the conduction band minimum for the 4/1 Si/O structure is located at the gamma point in contrast to bulk silicon (Si), whereas the valence band minimum occurs at the edge of the Brillouin zone in the (001) direction which we refer to as the Z point. One may also note the greater curvature of the conduction band minimum for the 4/1 Si/O structure compared to the curvature of the conduction band minimum for Si owing to the band splitting due to the perturbation introduced by the additional oxygen layer.

FIG. 4B shows the calculated band structure from the Z point for both bulk silicon (continuous lines) and for the 4/1 Si/O superlattice 25 (dotted lines). This figure illustrates the enhanced curvature of the valence band in the (100) direction.

FIG. 4C shows the calculated band structure from both the gamma and Z point for both bulk silicon (continuous lines) and for the 5/1/3/1 Si/O structure of the superlattice 25′ of FIG. 3 (dotted lines). Due to the symmetry of the 5/1/3/1 Si/O structure, the calculated band structures in the (100) and (010) directions are equivalent. Thus the conductivity effective mass and mobility are expected to be isotropic in the plane parallel to the layers, i.e. perpendicular to the (001) stacking direction. Note that in the 5/1/3/1 Si/O example the conduction band minimum and the valence band maximum are both at or close to the Z point.

Although increased curvature is an indication of reduced effective mass, the appropriate comparison and discrimination may be made via the conductivity reciprocal effective mass tensor calculation. This leads Applicants to further theorize that the 5/1/3/1 superlattice 25′ should be substantially direct bandgap. As will be understood by those skilled in the art, the appropriate matrix element for optical transition is another indicator of the distinction between direct and indirect bandgap behavior.

In accordance with one advantageous aspect, one or more of several elements, such as nitrogen (N), germanium (Ge), fluorine (F), aluminum (Al), gallium (Ga), indium (In), carbon (C), etc., may be co-implanted with boron (or as a replacement for boron) or other semiconductor dopant material for halo/SDE and/or deep source-drain regions, for MOS devices built using the above-noted high-mobility superlattice films for the channel region, for example. Various examples of MOS structures including such a superlattice channel region are set forth in U.S. Pat. Nos. 6,897,472 and 6,830,964, and co-pending U.S. application Ser. Nos. 10/941,062, 10/940,594, 11/381,787 and 11/381,794, all of which are assigned to the present Assignee and are hereby incorporated herein in their entireties by reference.

This technique may be used with conventional gate dielectrics (e.g., SiO₂) as well as high-K dielectrics, as described further in co-pending U.S. application Ser. Nos. 11/136,881 and 11/136,747, which are assigned to the present Assignee and are hereby incorporated herein in their entireties by reference. Applicants believe, without wishing to be bound thereto, that this technique will advantageously help retard boron diffusion laterally along the superlattice channel.

Several process variations may also be used where the additional dopant material (e.g., N, Ge, F, Al, Ga, In, C, etc.,) may be implanted first, followed by a high-temperature step (e.g., 1000° C., 5 sec N₂ or a spike anneal) to anneal out damage caused by the implant of these heavier atoms, which can be followed by the boron implant for halo, SDE or SD regions, for example. The exact conditions for the implants, thermal anneal and process sequence will vary for different technologies based upon the particular process/device parameters in use, as will be appreciated by those skilled in the art. One potential advantage of using indium it is that is in Group III (i.e., the same as boron), while the use of Ge (Group IV) may also be advantageous in that it is electrically similar to silicon.

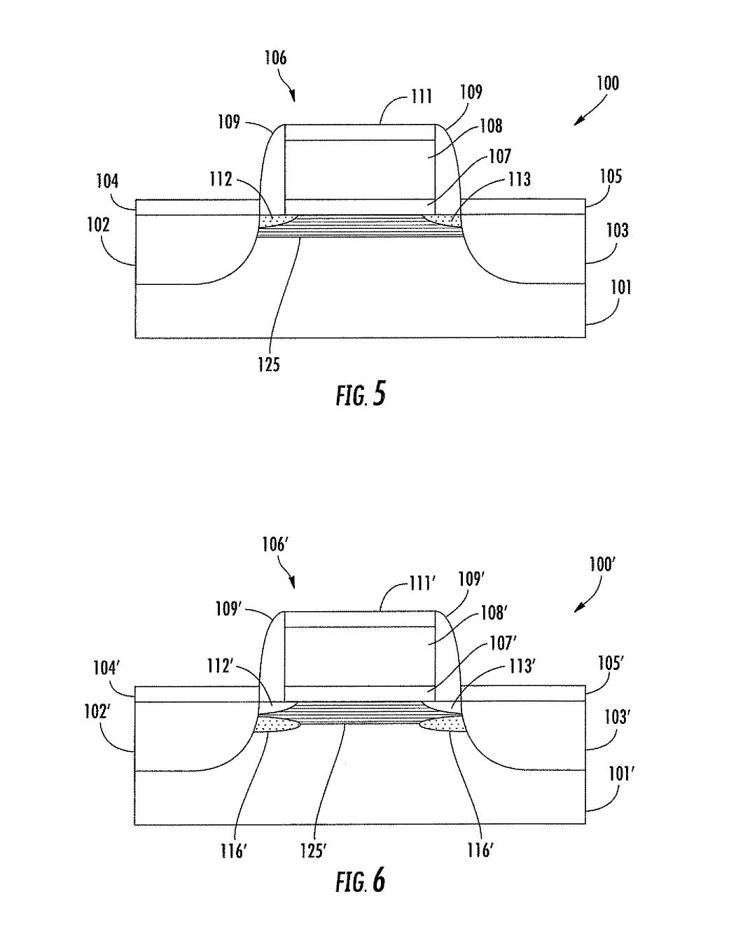

Turning now to FIGS. 5-7, various examples of semiconductor devices are now described in which a second dopant is implanted (or co-implanted) along with a first dopant, such as boron, in one or more regions adjacent the source and drain to advantageously help reduce diffusion of the first dopant. In the example of FIG. 5, a semiconductor device 100 illustratively includes a MOSFET formed on a substrate 101. The MOSFET illustratively includes a channel 125 which may comprise one or more superlattices, such as those described above. The MOSFET further illustratively includes a source 102 and a drain 103 on opposing sides of the superlattice channel 125, which have respective source and drain contacts 104, 105 thereon, and a gate 106 adjacent the superlattice channel. More particularly, the gate 106 illustratively includes a gate dielectric layer 107 overlying the superlattice channel 125 and a gate electrode layer 108 overlying the gate dielectric layer. Sidewall spacers 109 are illustratively adjacent the gate electrode layer 108, and a gate contact 111 overlies the gate electrode layer.

As noted above, a first dopant, such as boron, may be implanted in the source 102 and drain 103, as well as in a source extension region 112 and a drain extension region 113. However, in the present example, the source and drain extension regions, 112, 113 are also co-implanted with a second or additional dopant (shown with stippling) that is different than the first dopant, such as one of those listed above (e.g., N, Ge, F, Al, Ga, In, C, etc.,). This may advantageously help prevent undesired boron creep or diffusion inwardly from the source and drain extension regions 112, 113 toward the center of the superlattice channel 125.

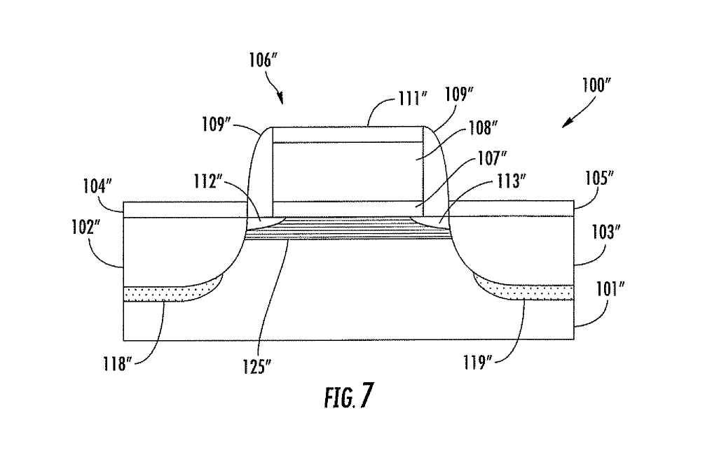

In the example of FIG. 6, the second dopant is advantageously implanted as a halo implant 116′ in a halo region adjacent the source 102′ and the drain 103′. Here again, this may advantageously help reduce diffusion of the first dopant in the halo region inwardly toward the middle or center of the superlattice channel 125′. In still another example shown in FIG. 7, the second dopant is implanted in a deep source region 118′ and a deep drain region 119′ in the substrate 101″ beneath the source 102″ and the drain 103″, respectively. This may advantageously help prevent diffusion of the first dopant into the body of the MOSFET or into the superlattice channel 125″, for example.

Many modifications and other embodiments will come to the mind of one skilled in the art having the benefit of the teachings presented in the foregoing descriptions and the associated drawings. Therefore, it is understood that the invention is not to be limited to the specific embodiments disclosed herein provided by way of example.

That which is claimed is:

1. A semiconductor device comprising:
a substrate;
at least one MOSFET adjacent said substrate and comprising a superlattice channel including a plurality of stacked groups of layers, a source and a drain adjacent said superlattice channel, and a gate adjacent said superlattice channel;
each group of layers of said superlattice channel comprising a plurality of stacked base semiconductor monolayers defining a base semiconductor portion and at least one non-semiconductor monolayer constrained within a crystal lattice of adjacent base semiconductor portions;
a first dopant in at least one region adjacent at least one of said source and drain; and
a second dopant in the at least one region, said second dopant being different than said first dopant and reducing diffusion thereof.

2. The semiconductor device of claim 1 wherein the at least one region comprises a halo region adjacent said source and drain.

3. The semiconductor device of claim 1 wherein the at least one region comprises a source extension region adjacent said source and a drain extension region adjacent said drain.

4. The semiconductor device of claim 1 wherein the at least one region comprises a deep source region adjacent said source and a deep drain region adjacent said drain.

5. The semiconductor device of claim 1 wherein said first dopant comprises boron.

6. The semiconductor device of claim 1 wherein said second dopant comprises at least one of nitrogen, germanium, fluorine, aluminum, gallium, indium, and carbon.

7. The semiconductor device of claim 1 further comprising a contact layer on at least one of said source and drain.

8. The semiconductor device of claim 1 wherein each base semiconductor portion comprises silicon.

9. The semiconductor device of claim 1 wherein each base semiconductor portion comprises germanium.

10. The semiconductor device of claim 1 wherein said at least one non-semiconductor layer comprises oxygen.

11. The semiconductor device of claim 1 wherein said at least one non-semiconductor monolayer comprises a non-semiconductor selected from the group consisting of oxygen, nitrogen, fluorine, and carbon-oxygen.

12. The semiconductor device of claim 1 wherein said gate comprises an oxide layer overlying said superlattice channel and a gate electrode overlying said oxide layer.

13. The semiconductor device of claim 1 wherein said superlattice channel further comprises a base semiconductor cap layer on an uppermost group of layers.

14. The semiconductor device of claim 1 wherein at least some semiconductor atoms from opposing base semiconductor portions are chemically bound together through said non-semiconductor layer therebetween.

15. A method for making a semiconductor device comprising:
forming at least one MOSFET adjacent a substrate, the at least one MOSFET comprising a superlattice channel including a plurality of stacked groups of layers, a source and a drain adjacent the superlattice channel, a gate adjacent the superlattice channel, a first dopant in at least one region adjacent at least one of the source and drain, and a second dopant in the at least one region, the second dopant being different than the first dopant and reducing diffusion thereof;
each group of layers of the superlattice channel comprising a plurality of stacked base semiconductor monolayers defining a base semiconductor portion and at least one non-semiconductor monolayer constrained within a crystal lattice of adjacent base semiconductor portions.

16. The method of claim 15 wherein the at least one region comprises a halo region adjacent the source and drain.

17. The method of claim 15 wherein the at least one region comprises a source extension region adjacent the source and a drain extension region adjacent the drain.

18. The method of claim 15 wherein the at least one region comprises a deep source region adjacent the source and a deep drain region adjacent the drain.

19. The method of claim 15 wherein the first dopant comprises boron.

20. The method of claim 15 wherein the second dopant comprises at least one of nitrogen, germanium, fluorine, aluminum, gallium, indium, and carbon.

21. The method of claim 15 wherein forming further comprises co-implanting the first and second dopants in the at least one region.

22. The method of claim 15 further comprising forming a contact layer on at least one of the source and drain regions.

23. The method of claim 15 wherein each base semiconductor portion comprises silicon.

24. The method of claim 15 wherein each base semiconductor portion comprises germanium.

25. The method of claim 15 wherein the at least one non-semiconductor layer comprises oxygen.

26. The method of claim 15 wherein the at least one non-semiconductor monolayer comprises a non-semiconductor selected from the group consisting of oxygen, nitrogen, fluorine, and carbon-oxygen.

27. The method of claim 15 wherein the gate comprises an oxide layer overlying the superlattice channel and a gate electrode overlying the oxide layer.

28. The method of claim 15 wherein the superlattice channel further comprises a base semiconductor cap layer on an uppermost group of layers.

29. The method of claim 15 wherein at least some semiconductor atoms from opposing base semiconductor portions are chemically bound together through the non-semiconductor layer therebetween.
